(19) United States
(12) Patent Application Publication
(10) Pub. No.: US 2016/0028357 A1
(43) Pub. Date: Jan. 28, 2016

(54) DISPLAY DEVICE, BODY DEVICE, AND INFORMATION PROCESSING DEVICE

(71) Applicant: FUJITSU LIMITED, Kawasaki-shi (JP)

(72) Inventors: Noriharu OKADA, Kawasaki (JP); Masatoshi KIMURA, Kawasaki (JP)

(21) Appl. No.: 14/730,875

(22) Filed: Jun. 4, 2015

(30) Foreign Application Priority Data
Jul. 25, 2014 (JP) 2014-152236

(51) Int. Cl. H03G 3/20; G09G 3/34; H04R 1/00

(52) U.S. Cl. CPC H03G 3/20; H04R 1/00; G09G 3/3406; H04R 2499/15

(57) ABSTRACT

A display device that is detachable from a body device that includes a first speaker, the display device includes, a second speaker; a processor; and a memory that stores a plurality of instructions, which when executed by the processor, cause the processor to execute: switching an adjustment mode to an audio adjustment mode; and transmitting, to the body device, a volume value of audio that is to be output from one of the first speaker and the second speaker, the volume value being adjusted when the adjustment mode is switched to the audio adjustment mode.

### CROSS-REFERENCE TO RELATED APPLICATION

This application is based upon and claims the benefit of priority of the prior Japanese Patent Application No. 2014-152236 filed on Jul. 25, 2014, the entire contents of which are incorporated herein by reference.

### FIELD

The embodiments discussed herein are related to, for example, a display device, a body device, and an information processing device.

### BACKGROUND

In a desktop personal computer (PC) and a laptop PC in which a display device (display) is integrated with a body device, volume adjustment (audio codec) of a speaker and brightness adjustment (embedded controller) of a screen are controlled by an operating system (OS). The related art is disclosed in, for example, Japanese Laid-open Patent Publication No. 2003-140879 and Japanese Laid-open Patent Publication No. 2005-115550.

In a case of a PC the display device of which is detachable from the body device, the user operates a button that is provided on the display device, causes a setting screen by which volume adjustment and the like are performed to be displayed on the display, and adjusts the brightness and the volume on the display device side by operating an icon on the screen. A display method by which a setting screen including an icon that allows volume adjustment and the like to be performed is displayed so as to be overlapped with a movie on the display is also called on-screen display (OSD). At that time, brightness adjustment and volume adjustment that are performed on the display device side are performed independently of the control by the OS of the body device.

### SUMMARY

In accordance with an aspect of the embodiments, a display device that is detachable from a body device that includes a first speaker, the display device includes, a second speaker; a processor; and a memory that stores a plurality of instructions, which when executed by the processor, cause the processor to execute: switching an adjustment mode to an audio adjustment mode; and transmitting, to the body device, a volume value of audio that is to be output from one of the first speaker and the second speaker, the volume value being adjusted when the adjustment mode is switched to the audio adjustment mode.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawing of which:

FIG. 1 is a diagram illustrating an example of a hardware configuration of a body device according to an embodiment;

FIG. 2 is a diagram illustrating an example of a hardware configuration of a display device according to the embodiment;

FIG. 3 is a diagram illustrating an example of function configurations of the body device and the display device according to the embodiment;

FIGS. 4A to 4C are diagrams illustrating a screen example of OSD according to the embodiment;

FIG. 5 is a flowchart illustrating an example of mode switching processing according to the embodiment;

FIG. 6 is a time chart illustrating mode switching and adjustment of volume and so forth according to the embodiment; and

FIG. 7 is a flowchart illustrating an example of adjustment processing according to the embodiment.

### DESCRIPTION OF EMBODIMENTS

Embodiments are described below with reference to the accompanying drawings. In the specification and drawings, the same reference numeral is assigned to the elements that have substantially the same function configuration, and the duplicated description is omitted herein.

An information processing device according to an embodiment is described below. The information processing device according to the embodiment includes a body device and a display device that is detachable from the body device. A device that is detachable from the body device is not limited to a display as long as the device includes a radio communication function. For example, the device that is detachable from the body device may be game equipment that includes a display unit and reproduction equipment that includes a display unit.

A display device 3 and a body device 1 have a physically detachable docking structure. Due to such a configuration, the information processing device according to the embodiment may be used so that the display device 3 is docked and integrated with the body device 1, or the display device 3 is detached from the body device 1.

In the information processing device according to the embodiment, which is described below, the body device 1 is transmission side equipment that transmits image data, and the display device 3 is reception side equipment that receives the image data that has been transmitted from the body device 1. That is, the body device 1 operates as an access point (AP), and the display device 3 operates as a station (STA).

Hardware configurations of the body device 1 and the display device 3 are described below. After that, function configurations of the body device 1 and the display device 3 are described. After that, switching processing of a brightness adjustment mode and a volume adjustment mode, and adjustment processing of a brightness value and a volume value are described.

[Hardware Configuration of Body Device]

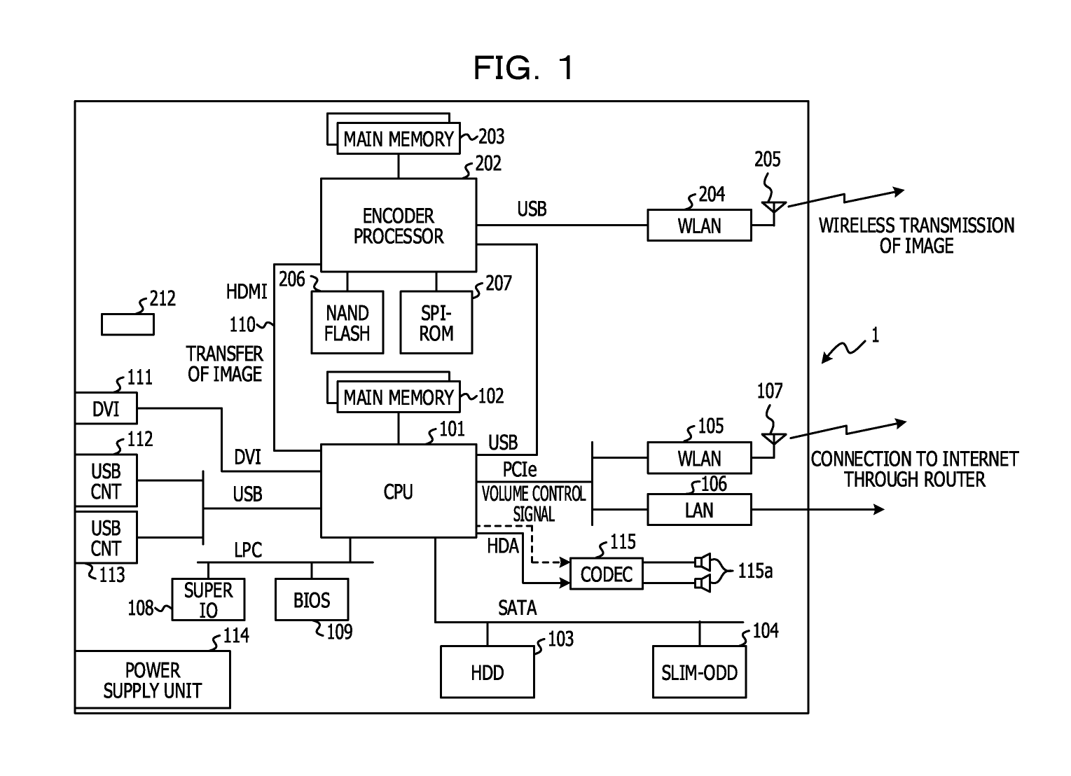

First, the hardware configuration of the body device 1 according to the embodiment is described with reference to FIG. 1. FIG. 1 is a diagram illustrating an example of the hardware configuration of the body device 1 according to the embodiment.

The body device 1 according to the embodiment includes a central processing unit (CPU) 101, a main memory 102, a hard disk drive (HDD) 103, and a slim optical disk drive (ODD) 104. In addition, the body device 1 includes a wireless local area network (WLAN) 105, a LAN 106, an antenna 107, and a super input/output (IO)) 108. In addition, the body device 1 includes a basic IO system (BIOS) memory 109, a high definition multimedia interface (HDMI) (registered trademark) 110, and a digital visual interface (DVI) 111. In addition, the body device 1 includes universal serial bus controllers (USBCNTs) 112 and 113, and a power supply unit 114. In addition, the body device 1 includes a codec 115 and a first speaker 115a. In addition, the body device 1 according to the embodiment includes an encoder processor 202, a main memory 203, a WLAN 204, an antenna 205, a NAND flash memory 206, an SPI-ROM 207, and a docking structure 212.

The CPU 101 is an example of a main processing circuit in the body device 1. The main memory 102, the HDD 103, and the Slim-ODD 104 are connected to the CPU 101 through buses. In addition, the WLAN 105, the LAN 106, the Super IO 108, the BIOS memory 109, the HDMI 110, the DVI 111, and the USBCNTs 112 and 113 are connected to the CPU 101 through buses. The WLAN 105 is connected to the antenna 107. The power supply unit 114 is a power source that supplies power to each of the units such as the CPU 101. In FIG. 1, a power supply line from the power supply unit 114 to each of the units is not illustrated.

The HDD 103 is a non-volatile storage device that stores a program and data. The program and the data that are stored in the HDD 103 include an OS that is basic software that controls the entire device, and application software that provides various functions on the OS. The HDD 103 stores the OS, an installed application, an uninstaller, a registry, and the like. The HDD 103 stores an application (program) that is used to execute mode switching processing and adjustment processing of volume and the like, which are described below.

The Slim-ODD 104 is an optical disk drive. When a distribution-type application, update data, and the like are distributed using an optical disk, the Slim-ODD 104 reads data from the distributed optical disk and stores the data.

The WLAN 105 performs radio communication through the antenna 107. The WLAN 105 is connected to a network such as the Internet, through a router, and transmits and receives data to and from the outside. The LAN 106 is also connected to the network such as the Internet, and transmits and receives data to and from the outside. The distribution-type application, the update data, and the like may be downloaded, for example, through the WLAN 105 or the LAN 106.

The Super IO 108 is an IO interface. To the Super IO 108, for example, a keyboard and a mouse may be connected. The BIOS memory 109 is a non-volatile storage device that stores a program group (for example, a BIOS) that controls a disk drive, a keyboard, a video card, and the like that are connected to the computer.

The HDMI 110 is an interface that is used to transmit a digital movie and audio. In the embodiment, image data and the like that are stored in the body device 1 is transmitted from the body device 1 to the display device 3 side through the HDMI 110 by radio communication.

The DVI 111 is an interface that may be connected to, for example, a monitor, and outputs the image data and the like that are stored in the body device 1, to the monitor. Each of the USBCNTs 112 and 113 is a control circuit of a USB device that is connected to a USB connector that is included in the body device 1.

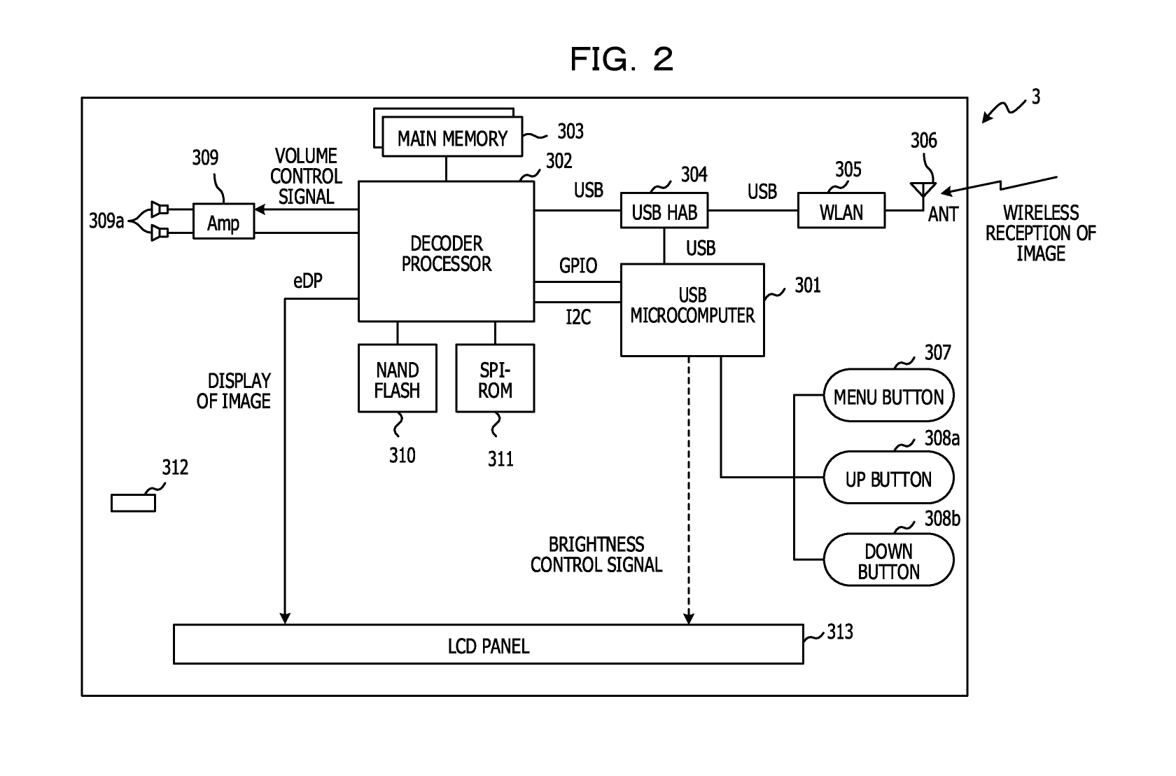

The first speaker 115a is connected to the CPU 101, through the codec 115. The codec 115 converts a digital signal of an audio control signal into an analog signal, and outputs the amplified audio through the first speaker 115a. The volume control signal includes pieces of information on the audio and the volume value. In the information processing device according to the embodiment, the first speaker 115a is provided in the body device 1, a second speaker 309a is provided in the display device 3 illustrated in FIG. 2, and switching between the first speaker 115a and the second speaker 309a may be performed.

The main memory 203, the NAND flash memory 206, and the SPI-ROM 207 are connected to the encoder processor 202 through buses. The WLAN 204 is connected to the encoder processor 202 through a USB. In addition, the WLAN 204 is connected to the antenna 205, and transmits the image data of the body device 1 to the display device 3.

The encoder processor 202 is a specific processor that consumes low power and executes processing of a single function as compared with the CPU 101. The image data of the body device 1 is input from the CPU 101 to the encoder processor 202 through the HDMI 110. For example, the encoder processor 202 compresses and encodes the image data, and then transmits the image data to the display device 3 through the WLAN 204.

The docking structure 212 is a connector having a structure that is connectable to a docking structure 312 illustrated in FIG. 2. In the docking structure 212, a plurality of terminals are provided, and the physical docking with the docking structure 312 enables the body device 1 and the display device 3 to be electrically connected to each other.

[Hardware Configuration of Display Device]

The hardware configuration of the display device 3 according to the embodiment is described with reference to FIG. 2. FIG. 2 is a diagram illustrating an example of the hardware configuration of the display device 3 according to the embodiment.

The display device 3 according to the embodiment includes a USB microcomputer 301, a decoder processor 302, a main memory 303, a USB hub 304, a WLAN 305, and an antenna 306. In addition, the display device 3 includes a NAND flash memory 310 and an SPI-ROM 311. In addition, the display device 3 includes a menu button 307, an up button 308a, a down button 308b, an amplifier 309, and the second speaker 309a.

The decoder processor 302 is connected to the USB microcomputer 301, the main memory 303, the USB hub 304, the NAND flash memory 310, and the SPI-ROM 311 through buses. The WLAN 305 is connected to the decoder processor 302 through the USB hub 304. The WLAN 305 is connected to the antenna 306, and receives image data from the encoder processor 202 of the body device 1. The USB hub 304 performs relay between the WLAN 305 and the decoder processor 302. The decoder processor 302 performs decoding and decompressing of the transferred image data, and displays the image data on a liquid crystal display (LCD) panel 313. The LCD panel 313 is an example of a display (display unit) that is provided on the display device 3.

The USB microcomputer 301 outputs a brightness control signal that is described below to the LCD panel 313. The brightness control signal includes pieces of information on a brightness value and ON/OFF of the backlight of the LCD panel 313. The USB microcomputer 301 controls the brightness and the ON/OFF of the backlight of the LCD panel 313, based on the brightness control signal.

The decoder processor 302 is a specific processor that consumes low power and executes processing having a single function as compared with the CPU 101. Therefore, the weight of the portable display device 3 may be reduced. Each of the NAND flash memory 310 and the SPI-ROM 311 stores various pieces of data and programs such as programs that are executed by the decoder processor 302.

Pieces of image data are continuously transferred between the decoder processor 302 and the encoder processor 202, and the movie thereof is displayed on the LCD panel 313. When the decoder processor 302 is caused to execute processing that is different from the transfer processing of the pieces of image data under such a condition, the transfer processing of the pieces of image data is temporarily suspended, and it is probable that the quality of the movie that is displayed on the LCD panel 313 is degraded. Therefore, the decoder processor 302 according to the embodiment is not caused to execute the processing other than the transfer processing of the pieces of image data as much as possible, so that the stability of the quality of the movie that is displayed on the LCD panel 313 of the display device 3 is secured.

Therefore, in the embodiment, the USB microcomputer 301 executes the switching processing of the adjustment mode of volume and brightness, and the adjustment processing of a volume value and a brightness value. The decoder processor 302 controls OSD of a setting screen by which the brightness and the volume is set, which is used for the adjustment processing by the USB microcomputer 301. That is, the decoder processor 302 displays the setting screen of the brightness and so forth on the LCD panel 313 so as to cause the setting screen to be superimposed over the image data.

The menu button 307 is a physical button that is pressed to switch the adjustment mode of the brightness and the volume. Each of the up button 308a and the down button 308b is a physical button that is pressed to change a setting value in each of the adjustment modes. That is, when the menu button 307 is pressed, switching between the brightness adjustment mode and the volume adjustment mode is performed. When the current adjustment mode is the brightness adjustment mode, the brightness value may be increased or decreased by pressing the up button 308a or the down button 308b. When the current adjustment mode is the volume adjustment mode, the volume value may be increased or decreased by pressing the up button 308a or the down button 308b. The menu button 307, the up button 308a, and the down button 308b are connected to the USB microcomputer 301. The USB microcomputer 301 performs switching of the adjustment mode and adjustment of the brightness value and the volume value, in accordance with an operation of the menu button 307, the up button 308a, and the down button 308b by the user.

The amplifier 309 and the second speaker 309a are connected to the decoder processor 302. The amplifier 309 amplifies an audio control signal, and outputs the amplified audio control signal through the second speaker 309a.

Among the current adjustment mode and the adjusted brightness value or volume value, which have been obtained by the USB microcomputer 301, the adjusted volume value is output to the decoder processor 302 in the state of being included in the audio control signal. In addition, the volume value is transmitted from the decoder processor 302 to the encoder processor 202 on the body device 1 side, and is transmitted from the encoder processor 202 to the CPU 101.

The CPU 101 causes the OS of the HDD 103 to operate, based on the received adjusted setting value, and controls the volume of audio that is output from the first speaker 115a, based on the adjusted volume value that is included in the audio control signal. In addition, the adjusted volume value is stored in the HDD 103. Therefore, in the information processing device according to the embodiment, the volume of each of the first speaker 115a that is included in the body device 1 and the second speaker 309a that is included in the display device 3 may be managed in an integrated manner. Thus, it may be avoided that improper volume is obtained when audio is output from the first speaker 115a in a state in which the display device 3 is set to the body device 1.

The docking structure 312 is a connector that has a structure capable of being connected to the docking structure 212.

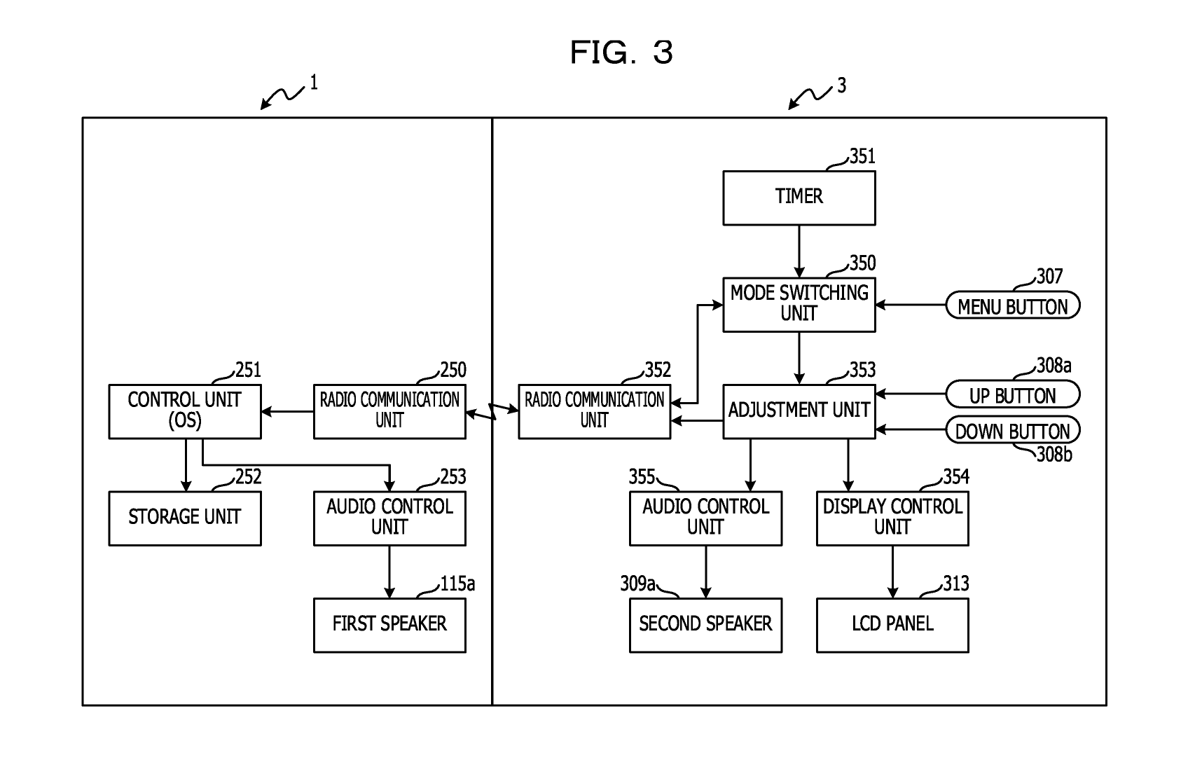

The hardware configurations of the body device 1 and the display device 3 according to the embodiment are described above. An example of function configurations of the body device 1 and the display device 3 according to the embodiment are described with reference to FIG. 3.

[Function Configuration of Body Device]

The body device 1 includes a radio communication unit 250, a control unit 251, a storage unit 252, and an audio control unit 253. The radio communication unit 250 transmits and receives image data and various pieces of control data to and from the display device 3. The radio communication unit 250 is an example of a second communication unit that receives, from the display device 3, a volume value of audio that is output from the second speaker 309a, which has been adjusted when the adjustment mode is switched to the audio adjustment mode.

The control unit 251 controls the entire body device 1. For example, the control unit 251 controls each function of the body device 1 by starting up the OS. The storage unit 252 saves the volume value that has been received from the display device 3.

The audio control unit 253 controls a volume value of audio that is output from the first speaker 115a, based on the volume value that has been received from the display device 3.

In the embodiment, the function of the radio communication unit 250 is mainly achieved by the WLAN 204. The functions of the control unit 251 and the audio control unit 253 are mainly achieved by the CPU 101. The function of the storage unit 252 is mainly achieved by the HDD 103. The CPU 101 saves the volume value that has been received from the display device 3 in the HDD 103. The CPU 101 outputs audio having a desired volume through the first speaker 115a, based on the volume value.

[Function Configuration of Display Device]

The display device 3 includes a mode switching unit 350, a timer 351, a radio communication unit 352, an adjustment unit 353, a display control unit 354, and an audio control unit 355.

The mode switching unit 350 switches the current adjustment mode from one of the audio adjustment mode and the brightness adjustment mode to the other mode when the menu button 307 is pressed. The mode switching unit 350 switches the adjustment mode between the brightness adjustment mode and the volume adjustment mode again when the menu button 307 is pressed again during the OSD.

The timer 351 counts a certain time period. The adjustment unit 353 adjusts the volume value or the brightness value in accordance with the current adjustment mode.

When the current adjustment mode is the audio adjustment mode, the adjustment unit 353 changes the setting value (volume value) of the volume in accordance with a user operation of the up button 308a or the down button 308b. The adjustment unit 353 may change the volume value in accordance with a user operation of a plus (+) button or a minus (−) button on the setting screen for volume adjustment, which has been displayed so as to be superimposed over a movie that has been drawn on the LCD panel 313.

When the current adjustment mode is the brightness adjustment mode, the adjustment unit 353 changes the setting value of the brightness (brightness value), in accordance with a user operation of the up button 308a or the down button 308b. The adjustment unit 353 may change the brightness value in accordance with a user operation of a plus (+) button or a minus (−) button on the setting screen for brightness adjustment, which has been displayed so as to be superimposed over the movie on the LCD panel 313.

The display control unit 354 controls the brightness of the LCD panel 313. The display control unit 354 controls the brightness of the LCD panel 313, based on the brightness value that has been adjusted when the adjustment mode is switched to the brightness adjustment mode.

In addition, in accordance with switching of the adjustment mode, the display control unit 354 performs switching between the setting screen by which the volume value is adjustable and the setting screen by which the brightness value is adjustable, and displays the setting screen so as to be superimposed over the image data that has been drawn on the LCD panel 313 (executes the OSD).

The audio control unit 355 controls the volume of audio that is output from the second speaker 309a. The audio control unit 355 controls the volume of the audio that is output from the second speaker 309a, based on the volume value that is adjusted when the adjustment mode is switched to the volume adjustment mode.

The radio communication unit 352 transmits the adjusted volume value to the body device 1. The radio communication unit 352 is an example of a first communication unit that transmits, to the body device 1, the volume value of audio that is output from the first or second speaker, which is adjusted when the adjustment mode is switched to the audio adjustment mode.

In the embodiment, the functions of the mode switching unit 350 and the adjustment unit 353 are mainly achieved by the USB microcomputer 301. The functions of the display control unit 354 and the audio control unit 355 are mainly achieved by the decoder processor 302. The function of the radio communication unit 352 is mainly achieved by the WLAN 305.

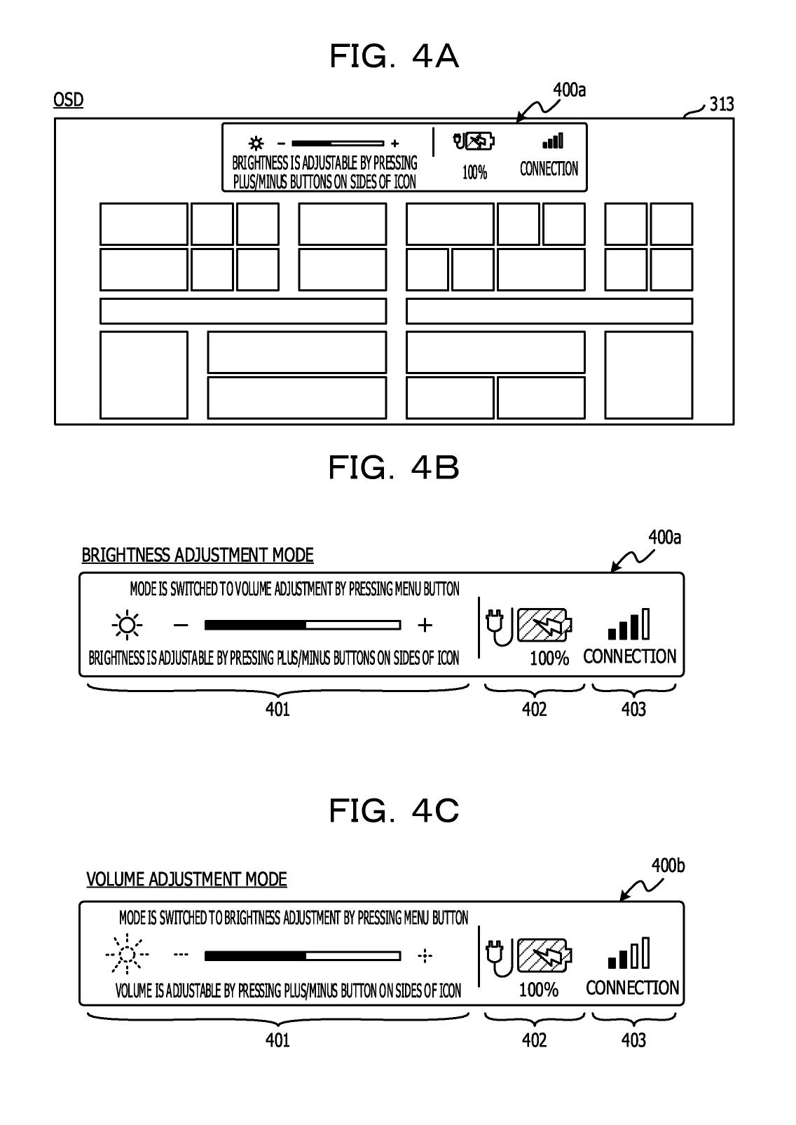

The function configurations of the body device 1 and the display device 3 according to the embodiment are described above. The switching of the adjustment mode and the OSD are described below with reference to FIG. 4.

[Switching of Adjustment Mode and OSD]

When the adjustment mode is switched to the brightness adjustment mode, as illustrated in FIG. 4B, a brightness adjustment setting screen 400a is displayed. On the brightness adjustment setting screen 400a, an icon 401 is displayed that allows the brightness of the LCD panel 313 to be adjusted when the user touches +/− buttons on the sides of the icon 401. In addition, on the setting screen 400a, an icon 402 that indicates the charge state of a battery that is not illustrated and is included in the display device 3, and an icon 403 that indicates the radio wave state in radio communication are displayed. As illustrated in FIG. 4A, the display control unit 354 displays the brightness adjustment setting screen 400a so as to cause the brightness adjustment setting screen 400a to be superimposed over the image data on the screen of the LCD panel 313 (executes the OSD).

When the adjustment mode is switched to the volume adjustment mode, as illustrated in FIG. 4C, a volume adjustment setting screen 400b is displayed. On the volume adjustment setting screen 400b, an icon 401 that allows the volume to be adjusted when the user touches +/− buttons on the sides of the icon 401, an icon 402 that indicates the charge state of a battery, and an icon 403 that indicates the radio wave state in radio communication are displayed. When the adjustment mode is switched to the volume adjustment mode, the display control unit 354 switches the brightness adjustment setting screen 400a to the volume adjustment setting screen 400b, and executes the OSD.

The user may adjust a brightness value (change the setting value) by operating the icons (+, −) that have been displayed on the brightness adjustment setting screen 400a. In addition, the user may adjust a brightness value by pressing the up button 308a and the down button 308b.

In addition, the user may adjust a volume value (change the setting value) on the display device 3 side by operating the icons (+, −) that have been displayed on the volume adjustment setting screen 400b. The user may adjust a volume value (change the setting value) on the body device 1 side by performing an operation to change the setting value of the volume on the screen of volume adjustment, which is provided by the OS. In the information processing device according to the embodiment, the first speaker 115a is provided in the body device 1, and the second speaker 309a is provided in the display device 3. Therefore, for example, in a state in which the display device 3 is detached from the body device 1, audio is output from the second speaker 309a, so that it is desirable that the volume of the audio of the second speaker 309a be adjusted. On the other hand, in a state in which the display device 3 is attached to the body device 1, it is also conceivable that audio is output from the first speaker 115a, not from the second speaker 309a. In that case, it is desirable that the body device 1 be notified of the volume value that has been adjusted on the display device 3 side, and that audio be output from the first speaker 115a based on the volume value.

For example, in a case where the audio quality of the first speaker 115a on the body device 1 side is better than that of the second speaker 309a, when the display device 3 is docked and integrated with the body device 1, it is preferable that automatic control be performed so that the first speaker 115a on the body device 1 side is preferentially used. In addition, when the display device 3 is detached from the body device 1, it is assumed that the user carries only the display device 3, and thus it is desirable that automatic control be performed so that the speaker to be used as an output destination is switched from the first speaker 115a to the second speaker 309a.

Even in such a case, in the information processing device according to the embodiment, the body device 1 is notified of the volume value that has been adjusted on the display device 3 side, and the display device 3 is notified of the volume value that has been adjusted on the body device 1 side. Therefore, the volume values of audio output from the first speaker 115a that is provided in the body device 1 and the second speaker 309a that is provided in the display device 3 are managed in an integrated manner in the control unit 251 on the body device 1 side. Therefore, it may be avoided that audio having improper volume is output from the first speaker 115a.

As described above, in the information processing device according to the embodiment, the user switches the adjustment mode by operating a physical button (menu button 307) depending on whether the user desires to adjust a volume value or a brightness value. When the adjustment mode is the volume adjustment mode, the control unit 251 of the body device 1 is notified of the adjusted volume. On the other hand, when the adjustment mode is the brightness adjustment mode, the adjusted brightness value is managed by the display device 3, and the body device 1 is not notified of the adjusted brightness value.

Therefore, in the information processing device according to the embodiment, the brightness value is controlled on the display device 3 side, and the body device 1 is not notified of the brightness value, so that a control time may be reduced, and the operability of the user may be increased. In addition, in the information processing device according to the embodiment, the adjustment mode may be switched using the menu button 307, and the brightness value or the volume value may be changed using the up button 308a and the down button 308b, so that the number of buttons may be reduced. Thus, the display device 3 may be provided the design of which is excellent, and the manufacturing cost of which is reduced.

When the display device 3 notifies the body device 1 of a volume value, the display device 3 transmits an audio control signal that includes the volume value to the body device 1. In addition, when the body device 1 notifies the display device 3 of a volume value, the body device 1 transmits an audio control signal that includes the volume value to the display device 3. Therefore, the latest volume value may be managed in either of the body device 1 and the display device 3. However, it is desirable that the display device 3 notifies the body device 1 of the volume value, but the body device 1 may not notify the display device 3 of the volume value.

[Switching Processing of Adjustment Mode]

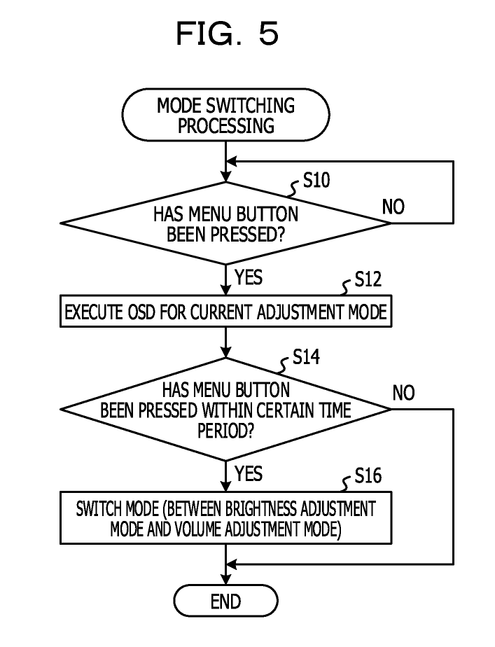

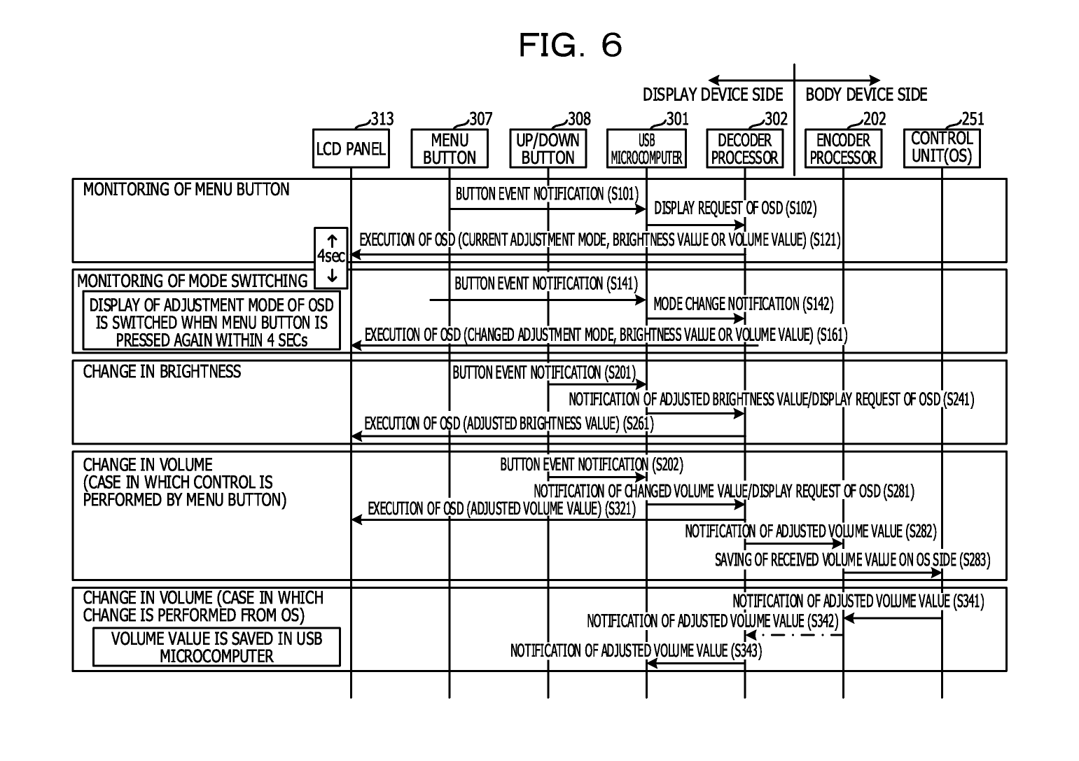

The switching processing of the adjustment mode and the adjustment processing of brightness and volume are described below with reference to FIGS. 5 to 7. First, the switching processing of the adjustment mode in the embodiment is described with reference to FIGS. 5 and 6. FIG. 5 is a flowchart illustrating an example of the switching processing of the adjustment mode in the embodiment. FIG. 6 is a time chart illustrating the switching processing of the adjustment mode and the adjustment processing of the volume and so forth in the embodiment. The switching processing of the mode is mainly executed by the mode switching unit 350 of the display device 3.

When the switching processing of the adjustment mode is started, the mode switching unit 350 determines whether or not the menu button 307 has been pressed (Step S10). Until the user presses the menu button 307, the mode switching unit 350 repeats the processing of Step S10 at a certain time interval. When the user presses the menu button 307, the processing proceeds to Step S12, and the mode switching unit 350 executes the OSD of the setting screen of the current adjustment mode.

As an example, as illustrated in “monitoring of the menu button” of FIG. 6, when the menu button 307 is pressed, a notification of a button event is transmitted to the USB microcomputer 301 (Step S101). The USB microcomputer 301 transmits a display request of the OSD to the decoder processor 302 (Step S102). When the decoder processor 302 receives the display request of the OSD, the decoder processor 302 executes the OSD of the setting screen of the current adjustment mode on the LCD panel 313 (Step S121). Therefore, the brightness value or the volume value of the current adjustment mode may be changed on the setting screen of the LCD panel 313.

For example, when the current adjustment mode is the brightness adjustment mode, the OSD of the brightness adjustment setting screen 400a illustrated in FIG. 4B is performed on the LCD panel 313 (see FIG. 4A). For example, when the current adjustment mode is the volume adjustment mode, the OSD of the volume adjustment setting screen 400b illustrated in FIG. 4C is performed on the LCD panel 313.

Returning to FIG. 5, the mode switching unit 350 determines whether or not the menu button 307 has been pressed within a certain time period (Step S14). If the user presses the menu button 307 again within the certain time period, the processing proceeds to Step S16, and the mode switching unit 350 switches the adjustment mode, and displays the setting screen of the switched adjustment mode on the LCD panel 313.

As an example, as illustrated in “monitoring of the mode switching” of FIG. 6, if the menu button 307 is pressed again within the certain time period (here, four seconds), a notification of a button event is transmitted to the USB microcomputer 301 (Step S141). The USB microcomputer 301 notifies the decoder processor 302 of the change in the adjustment mode (Step S142).

When the decoder processor 302 receives the change notification of the adjustment mode, the decoder processor 302 displays the setting screen for the changed adjustment mode on the LCD panel 313 so that the setting screen is superimposed over a movie on the LCD panel 313 (executes the OSD: Step S161). As a result, the brightness value or the volume value of the adjustment mode after the switching may be changed on the setting screen of the LCD panel 313.

For example, when the current adjustment mode is the brightness adjustment mode, the changed adjustment mode is the volume adjustment mode. As a result, the OSD is performed on the LCD panel 313 such that the screen is switched from the brightness adjustment setting screen 400a illustrated in FIG. 4B to the volume adjustment setting screen 400b illustrated in FIG. 4C.

When the current adjustment mode is the volume adjustment mode, the changed adjustment mode is the brightness adjustment mode. As a result, the OSD is performed on the LCD panel 313 such that the screen is switched from the volume adjustment setting screen 400b illustrated in FIG. 4C to the brightness adjustment setting screen 400a illustrated in FIG. 4B.

In Step S14, if the menu button 307 is not pressed again within the certain time period, the mode switching unit 350 ends the processing.

[Adjustment Processing of Brightness and Volume]

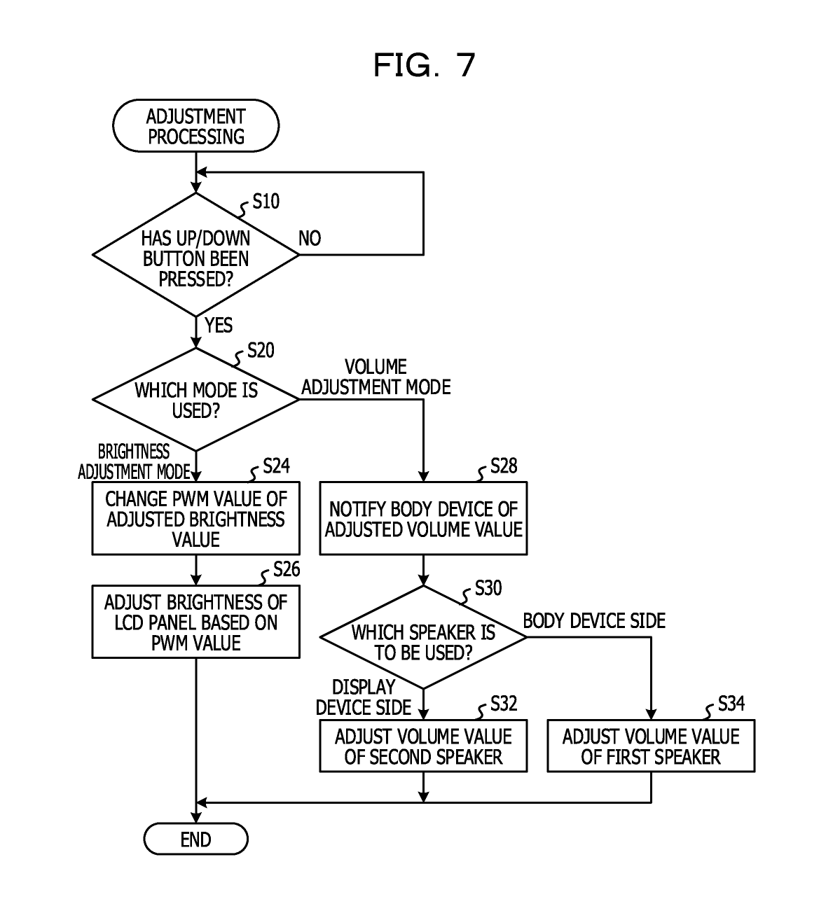

Next, the adjustment processing of the brightness and the volume in the embodiment is described below with reference to FIGS. 7 and 6. FIG. 7 is a flowchart illustrating an example of the adjustment processing of the brightness and the volume in the embodiment. The adjustment processing of the brightness and the volume is mainly executed by the adjustment unit 353 of the display device 3.

When the adjustment processing of the brightness and the volume is started, the adjustment unit 353 determines whether or not the up button 308a or the down button 308b has been pressed (Step S20). Until the user presses the up button 308a or the down button 308b, the adjustment unit 353 repeats the processing of Step S20 at a certain time interval. When the user presses the up button 308a or the down button 308b, the processing proceeds to Step S22, and the adjustment unit 353 determines whether the current adjustment mode is the volume adjustment mode or the brightness adjustment mode. If the adjustment unit 353 determines that the current adjustment mode is the brightness adjustment mode, a pulse width modulation (PWM) value is changed based on the adjusted brightness value (Step S24). In the case of reducing the brightness value, the PWM value is changed so that the pulse width is narrowed and the duty ratio of the PWM is increased. In the case of increasing the brightness value, the PWM value is changed so that the pulse width is increased and the duty ratio of the PWM is decreased.

After that, the display control unit 354 adjusts the brightness of the LCD panel 313 based on the PWM value, and controls the brightness of the screen (Step S26).

As an example, as illustrated in “change in the brightness” of FIG. 6, when the up button 308a or the down button 308b is pressed, a notification of a button event is transmitted to the USB microcomputer 301 (Step S201). The USB microcomputer 301 notifies the decoder processor 302 of the changed brightness value, and transmits a display request of the OSD to the decoder processor 302 (Step S241).

When the decoder processor 302 receives the display request of the OSD, the decoder processor 302 executes the OSD of the setting screen of the brightness value, on the LCD panel 313 (Step S261). Therefore, the user may change the brightness value by a touch operation on the LCD panel 313.

Returning to FIG. 7, in Step S22, if the adjustment unit 353 determines that the current adjustment mode is the volume adjustment mode, the radio communication unit 352 notifies the body device 1 of the adjusted volume value (Step S28). After that, the adjustment unit 353 determines a speaker to be used (Step S30). If the adjustment unit 353 determines that the speaker to be used is the speaker on the display device 3 side, the adjustment unit 353 adjusts the volume value of the second speaker 309a (Step S32), and the processing ends. When the adjustment unit 353 determines that the speaker to be used is the speaker on the body device 1 side, the adjustment unit 353 adjusts the volume value of the first speaker 115a (Step S34), and the processing ends.

In Steps S28 to S34, the example of the adjustment processing of the volume, which is executed on the display device 3 side, is illustrated. Such a specific example of the volume adjustment that is executed on the display device 3 side is described with reference to “change in the volume (case in which the control is performed by the menu button)” of FIG. 6. After that, an example of the volume adjustment that is executed on the body device 1 side is described with reference to “change in the volume (case in which the change is performed from the OS)” of FIG. 6.

In “change in the volume (case in which the control is performed by the menu button)” of FIG. 6, when the up button 308a or the down button 308b is pressed, a notification of a button event is transmitted to the USB microcomputer 301 (Step S202). The USB microcomputer 301 notifies the decoder processor 302 of the changed volume value, and transmits a display request of the OSD to the decoder processor 302 (Step S281).

When the decoder processor 302 receives the display request of the OSD, the decoder processor 302 executes the OSD of the setting screen of the volume value, on the LCD panel 313 (Step S321). Therefore, the user may change the volume value by a touch operation, on the LCD panel 313. The adjusted volume value is transferred from the decoder processor 302 to the encoder processor 202, and then to the control unit 251. Therefore, the adjusted volume value may be managed in an integrated manner by the OS of the control unit 251. Thus, the volume of audio that is output from the first speaker 115a may be adjusted appropriately, based on the adjusted volume value. As a result, even when the speaker to be used is switched from the second speaker 309a on the display device 3 side to the first speaker 115a on the body device 1 side, it may be avoided that audio having improper volume is output from the first speaker 115a.

The example of the volume adjustment that is executed on the body device 1 side is described with reference to “change in the volume (case in which the change is performed from the OS)” of FIG. 6. When the volume adjustment is performed by the control unit 251 (OS) of the body device 1 in accordance with a user operation, the control unit 251 (OS) notifies the encoder processor 202 of the adjusted volume value (Step 941). The encoder processor 202 notifies the decoder processor 302 of the adjusted volume value (Step S342), and the decoder processor 302 notifies the USB microcomputer 301 of the adjusted volume value (Step S343). Therefore, the volume of the audio that is output from the second speaker 309a may be adjusted appropriately based on the adjusted volume value. As a result, even when the speaker to be used is switched from the first speaker 115a on the body device 1 side to the second speaker 309a on the display device 3 side, it may be avoided that audio having improper volume is output from the second speaker 309a.

(Automatic Switching Processing of Speaker)

In the case of the volume adjustment, the determination of whether the volume of the first speaker 115a on the body device 1 side or the second speaker 309a on the display device 3 side is to be adjusted may be performed as follows. For example, any one of cases may be selected in which the volume of the first speaker 115a is preferentially adjusted, the volume of the second speaker 309a is preferentially adjusted, and the volume of a speaker that has been switched by automatic switching processing of a speaker is adjusted.

As a specific example, the control unit 251 of the body device 1 may perform automatic control by executing a program that is used for the automatic switching processing of a speaker so as to determine whether the first speaker 115a or the second speaker 309a is preferentially used when the display device 3 is docked and integrated with the body device 1. In such automatic control, it is desirable that switching to the first speaker 115a of the body device 1 be performed when the display device 3 is docked with the body device 1, and that switching to the second speaker 309a of the display device 3 be performed when the display device 3 is not docked with the body device 1.

(Automatic Switching Processing of Current Adjustment Mode)

In addition, the mode switching unit 350 of the display device 3 may execute the automatic switching processing of the current adjustment mode. For example, the mode switching unit 350 may detect whether or not the screen of the LCD panel 313 of the display device 3 is turned off, and may automatically switch the current adjustment mode onto the volume adjustment mode when the screen of the LCD panel 313 is turned off. Therefore, when the user desires to listen to music using the information processing device according to the embodiment in a state where the screen of the LCD panel 313 is turned off, the user may adjust the volume by operating the up button 308a and the down button 308b.

As described above, the information processing device according to the embodiment includes the body device 1 and the display device 3 that is detachable from the body device 1, and may manage the volume values that are adjustable by the body device 1 and the display device 3 in an integrated manner by the OS. As a result, it may be avoided that audio having improper volume is output from the first speaker 115a that is provided in the body device 1. In addition, it may be avoided that audio having improper volume is output from the second speaker 309a that is provided in the display device 3.

The display device, the body device, and the information processing device are described using the above-described embodiments. However, the display device, the body device, and the information processing device related to the technology discussed herein are not limited to the above-described embodiments, and various modifications and changes may be made within the scope of the technology discussed herein. In addition, matters described in the plurality of embodiments may be combined to the extent that they do not contradict. In addition, each of the functions that are achieved in the above-described display device, body device, and information processing device may be configured by hardware, software, or a combination of hardware and software.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A display device that is detachable from a body device that includes a first speaker, the display device comprising:
a second speaker;
a processor; and
a memory that stores a plurality of instructions, which when executed by the processor, cause the processor to execute:
switching an adjustment mode to an audio adjustment mode; and
transmitting, to the body device, a volume value of audio that is to be output from one of the first speaker and the second speaker, the volume value being adjusted when the adjustment mode is switched to the audio adjustment mode.

2. The device according to claim 1, wherein
the switching includes switching the adjustment mode to a brightness adjustment mode.

3. The device according to claim 2, further comprising:
controlling brightness of a display, based on a brightness value that is adjusted when the adjustment mode is switched to the brightness adjustment mode.

4. The device according to claim 3, wherein
the controlling includes switching a setting screen on which either of the volume value and the brightness value is adjustable in accordance with switching of the adjustment mode, and displaying the setting screen so as to be superimposed over image data on the display.

5. A body device from which a display device that includes a second speaker is detachable, the body device comprising:
a first speaker;
a processor; and
a memory that stores a plurality of instructions, which when executed by the processor, cause the processor to execute:
receiving, from the display device, a volume value of audio that is to be output from one of the first speaker and the second speaker, the volume value being adjusted when an adjustment mode is switched to an audio adjustment mode; and
controlling a volume value of audio that is to be output from the first speaker, based on the volume value that has been received from the display device.

6. An information processing device comprising:
a body device; and
a display device that is detachable from the body device, the display device including
a second speaker,
a first processor, and
a first memory that stores a plurality of instructions, which when executed by the first processor, cause the first processor to execute:
switching an adjustment mode to an audio adjustment mode; and
transmitting, to the body device, a volume value of audio that is to be output from one of the first speaker and the second speaker, the volume value being adjusted when the adjustment mode is switched to the audio adjustment mode, and
the body device including
a first speaker,
a second processor, and
a second memory that stores a plurality of instructions, which when executed by the second processor, cause the second processor to execute:
receiving the volume value from the display device; and
controlling a volume value of audio that is to be output from the first speaker, based on the volume value that has been received from the display device.

7. The information processing device according to claim 6, wherein
the switching includes switching the adjustment mode to a brightness adjustment mode.

8. The information processing device according to claim 7, further comprising:
controlling brightness of a display, based on a brightness value that is adjusted when the adjustment mode is switched to the brightness adjustment mode.

9. The information processing device according to claim 8, wherein
the controlling includes switching a setting screen on which either of the volume value and the brightness value is adjustable in accordance with switching of the adjustment mode, and displaying the setting screen so as to be superimposed over image data on the display.
